(19) United States
(12) Patent Application Publication
(10) Pub. No.: US 2026/0040892 A1
(43) Pub. Date: Feb. 5, 2026

(54) Overlay mark and overlay method of semiconductor structure

(71) Applicant: UNITED MICROELECTRONICS CORP., Hsin-Chu City (TW)

(72) Inventor: Po-Tsang Chen, Tainan City (TW)

(73) Assignee: UNITED MICROELECTRONICS CORP., Hsin-Chu City (TW)

(21) Appl. No.: 18/892,535

(22) Filed: Sep. 22, 2024

(30) Foreign Application Priority Data
Aug. 2, 2024 (TW) 113128882

(51) Int. Cl. H01L 21/66; G03F 1/44; H01L 23/544

(52) U.S. Cl. CPC H01L 22/12; G03F 1/44; H01L 22/30; H01L 23/544; H01L 2223/54426

(57) ABSTRACT

The invention provides an overlay mark, which comprises four sub-overlay marks, which together form an overlay mark, wherein each sub-overlay mark comprises a substrate and defines an inner region and an outer region, a plurality of first mandrel structures located in the inner region and a plurality of second mandrel structures located in the outer region, wherein the first mandrel structures are arranged in parallel with each other, and the second mandrel structures are also arranged in parallel with each other, and a plurality of strip-shaped mask layers are located in the inner region, wherein both sides of any first mandrel structure comprise a strip-shaped mask layer respectively. In addition, the invention also provides an overlay method of the semiconductor structure using the overlay mark.

### BACKGROUND OF THE INVENTION

### 1. Field of the Invention

The invention relates to the field of semiconductor manufacturing, in particular to a semiconductor overlay mark and a method for performing overlay measurement steps by using the overlay mark. The invention can reduce that numb of overlay mark, thereby achieving the advantage of reducing the occupied region of the cut path.

### 2. Description of the Prior Art

In the semiconductor manufacturing process, overlay and alignment mark are two important technical concepts. These technologies ensure that wafers can be accurately overlay on each layer in the multi-layer structure, thus ensuring the function and performance of the circuit. With the continuous progress of process technology, the importance of these technologies has gradually increased.

Overlay refers to the relative position overlapping between different lithography layers on the wafer in the semiconductor manufacturing process. Each layer of lithography pattern must be accurately aligned with the previous layer to ensure the correct realization of circuit functions. The overlay error is a measure of this overlay deviation, usually in nanometers. In advanced process nodes (such as 7 nm and below), the requirement for overlay accuracy becomes higher, because any slight error may lead to the decline or even failure of circuit performance. Overlay error can be divided into systematic error and random error. Systematic errors are caused by improper equipment calibration or design, which are predictable and can be reduced by correction methods, while random errors are unpredictable and caused by process or material defects, which need to be controlled by improving process stability.

In measuring overlay error, modern semiconductor manufacturing mainly uses optical or electron microscope technology. Optical overlay system uses optical overlay to measure marks, which has the advantages of high speed and convenient operation, and the accuracy can reach tens of nanometers. However, with the development of process technology, the demand for higher accuracy has prompted the emergence of electron beam overlay system. Electron beam overlay system can achieve higher accuracy by scanning overlay marks with electron beams, but its measurement speed is slow, which is suitable for process nodes with high accuracy requirements. In the actual process, in order to reduce the overlay error, a variety of correction methods will be adopted. Pre-correction is to overlap masks before exposure to reduce errors; Dynamic correction is real-time correction in the exposure process to improve the overlay accuracy, while post-correction is to correct errors through subsequent processes, such as ion implantation or chemical mechanical polishing (CMP) technology.

Alignment mark is a reference mark used for lithography alignment in semiconductor manufacturing. These marks are usually set at specific positions on the wafer as reference points for identification and alignment of lithography equipment. Accurate fabrication and identification of alignment marks is the basis of realizing high-precision overlay. Alignment marks are usually composed of specific geometric figures, such as crosses, rings or other high-contrast figures, so as to facilitate the identification and positioning of lithography equipment. These marks need to be made in the early stage of the process, and checked and corrected during each lithography layer to ensure the alignment accuracy of all lithography layers.

In the photolithography process of semiconductor manufacturing process, overlap plays an important role in marking. Lithography process is a technology that uses photoresist and photomask to form patterns on the wafer surface. First, the photoresist is coated on the surface of the wafer, and then the pattern is transferred to the photoresist through the photomask by using ultraviolet light or extreme ultraviolet light. This process requires accurate overlapping to ensure that each layer of graphics can accurately overlap with the previous layer of graphics. Overlay marks provide reference points for this precise overlapping, and lithography equipment corrects the position by recognizing these marks, thus ensuring the accurate transfer of graphics.

With the continuous progress of process technology, the requirements for overlay accuracy and overlay marking are getting higher and higher. In advanced process nodes, the overlay error needs to be controlled within a few nanometers, which puts high demands on process equipment and technology. In order to meet these challenges, new overlay and calibration techniques are constantly introduced into the process technology. However, the application of this technology has also brought some new challenges, such as stricter requirements for photoresist materials and mask design.

### SUMMARY OF THE INVENTION

The invention provides an overlay mark, which comprises four sub-overlay marks, which together form an overlay mark, wherein each sub-overlay mark comprises a substrate and defines an inner region and an outer region, a plurality of first mandrel structures are located in the inner region, and a plurality of second mandrel structures are located in the outer region, wherein the first mandrel structures are arranged in parallel with each other, and the second mandrel structures are also arranged in parallel with each other, and a plurality of strip-shaped mask layers are located in the inner region, wherein both sides of any first mandrel structure include one strip-shaped mask layer respectively.

The invention also provides an overlay measurement method of semiconductor structures, which comprises four sub-overlay marks on a scribe line of a substrate, wherein each sub-overlay mark comprises an inner region and an outer region, and a plurality of first mandrel structures are located on the substrate of the inner region and a plurality of second mandrel structures are located on the substrate of the outer region, so as to form a mask layer covering the first mandrel structure and the second mandrel structure, and form a first patterned photoresist layer on the mask layer. Performing a first overlay measurement step on the first patterned photoresist layer, the first mandrel structure and the second mandrel structure to form a second patterned photoresist layer on the mask layer, and performing a second overlay measurement step on the second patterned photoresist layer, the first mandrel structure and the second mandrel structure.

In the current technology, in order to improve the accuracy of overlay measurement steps, it may be carried out in several different overlay ways, including IBO (Image Based Overlay) measurement and DBO (Diffraction Based Overlay) measurement, etc. However, in the current technology, each overlay measurement step needs to form a separate overlay mark, when the size of components is getting smaller and smaller, too many overlay marks may not be accommodated in the limited space of the scribe line. The concept of the invention lies in that the same overlay mark is divided into different regions, such as an inner region and an outer region, and then the inner region and the outer region are respectively applied to different overlay measurement steps, such as an image based overlay (IBO) measurement step and a diffraction based overlay (DBO) measurement step. In other words, different regions of the same overlay mark can be used for different overlay measurement steps, so the original multiple overlay marks can be reduced to only a few overlay marks to complete the same overlay measurement step. In this way, the space of the scribe line can be greatly saved, and then the space of components can be saved. The invention conforms to the development trend of miniaturization of components and is also conducive to technical progress.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic top view of overlay marks in a scribe line according to an embodiment.

FIG. 2 is a top view of the overlay mark of the present invention.

FIG. 3, FIG. 4, FIG. 5, FIG. 6, FIG. 7, and FIG. 8 describe a part of the top view and a part of the cross-sectional view of the overlay mark shown in FIG. 2.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

First of all, the invention mainly relates to an overlay mark and a method for applying the overlay mark to carry out overlay measurement steps. Before describing the steps and structure of the invention, the basic knowledge of the invention is described first, so as to clearly understand the characteristics of the invention.

The invention is mainly applied to the overlay measurement step when forming fin structure and forming gate pattern in the semiconductor manufacturing process. The steps of the present invention generally include forming a mandrel pattern on a substrate, then transferring the pattern into the substrate by using the mandrel pattern and sidewall image transfer (SIT) technology to form a plurality of arrayed fin structures, then forming a gate pattern on the fin structures, and cutting the gate pattern.

Mandrel is a temporary structure in semiconductor manufacturing process, which is usually used as a template or support in patterning process. Its main function is to help form fine structures, especially in multiple patterning technologies such as self-aligned double patterning (SADP) and self-aligned quad patterning (SAQP). These technologies aim to overcome the resolution limitation of lithography technology and realize smaller feature size. In the manufacturing process, firstly, the pattern of the mandrel structure is formed, then the spacer is deposited, and then the mandrel structure is removed, leaving a fine pattern formed by the spacer. In this way, the mandrel structure, as a transitional structure, helps to realize high-precision pattern transfer, thus achieving smaller line width and higher pattern density.

Fin structure is the core part of FinFET structure, which represents one or more slender structures protruding from the substrate, and these structures form the channel region of the transistor. Current flows through these fin structures and is controlled by the gate around the fin structures. The three-dimensional structure design of fin structure increases the control region of gate to channel, which makes FinFET significantly improve the leakage current control and switching performance compared with the traditional planar transistor. The parallel use of multiple fin structures can further enhance the current capacity and improve the overall performance of the transistor. The fabrication of fin structures usually involves the formation of fin structure patterns first, and then a series of etching and deposition steps to ensure accuracy and consistency.

Gate is a fin-shaped switching element that controls the current to flow. In FinFET, the gate surrounds the sidewall and top of the fin structure, forming a three-dimensional surrounding structure, which provides better electric field control ability. The gate is usually made of polysilicon or other metal materials and covered with an insulating layer, such as a high dielectric constant material, to ensure effective control of the channel current during switching. The fabrication of the gate involves fine lithography and etching processes to ensure that the gate accurately surrounds each fin structure and provides the required electrical characteristics.

In addition, from the top view, the gates usually present a plurality of strip-shaped patterns separated from each other. In the actual process, in order to avoid the rounding of the pattern after etching, a plurality of strip-shaped gate continuous patterns are usually formed first, and then these strip-shaped gate continuous patterns are divided into a plurality of gate structure patterns separated from each other by a cutting step (also called a slot cut step), so that the corner shape of the cut gate pattern will be close to the original design pattern (such as a right angle), so that the rounding issue can be reduced.

As mentioned above, when the mandrel structure is formed, the continuous gate pattern is formed, and the continuous gate pattern is subjected to the gate cutting step, different photomasks are used to perform the photolithography etching step respectively, so as to transfer the pattern on the photomask to the substrate or the material layer. However, in the above-mentioned steps, it is necessary to carry out overlay measurement steps between different material layers to keep the components from being mis-alignment, which will lead to component damage. Therefore, when the above-mentioned elements are formed in the element region on the substrate, it is better to form corresponding overlay marks in the peripheral region (such as scribe lines) of the elements at the same time.

In the prior art, when each pattern layer is formed, overlay marks are simultaneously formed in the scribe line for overlay measurement with overlay marks of other material layers above and below. That is, each material layer corresponds to an overlay mark in at least one scribe line. In addition, in the current technology, in order to improve the accuracy of the overlay measurement step, it is possible to overlap with more than one different overlay measurement step, and after obtaining multiple sets of data respectively, one of the data is taken as the subsequent main data. For example, if a certain material layer is expected to be overlapped with other material layers on the upper and lower layers by two different overlay measurement steps, two overlay marks will be formed on the scribe line by the current technology and used for the two overlay measurement steps of this layer respectively.

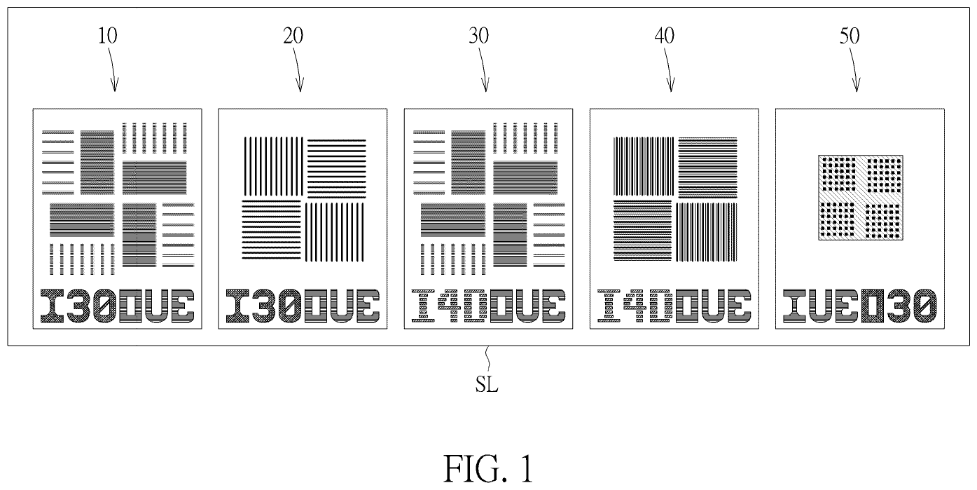

FIG. 1 shows a schematic top view of overlay marks in a scribe line according to an embodiment. Taking FIG. 1 as an example, the scribe line SL contains a plurality of overlay marks, namely the first overlay mark 10, the second overlay mark 20, the third overlay mark 30, the fourth overlay mark 40 and the fifth overlay mark 50. Wherein each overlay mark is formed by overlay marks of an upper layer and a lower layer, that is, after overlay marks of overlay marks of an upper layer and a lower layer respectively. For example, the first overlay mark 10 includes an overlay pattern of an overlay mark with a mandrel structure and an overlay mark with a gate pattern, and the subsequent overlay measurement step will be carried out with the IBO (image based overlay) measurement step. The second overlay mark 20 includes an overlay pattern of an overlay mark of a mandrel structure and an overlay mark of a gate pattern, and the subsequent overlay measurement step will be performed by a DBO (diffraction based overlay) measurement step. The third overlay mark 30 includes an overlay pattern of an overlay mark of a mandrel structure and an overlay mark of a gate slot, and the subsequent overlay measurement step will be performed by an IBO measurement step. The fourth overlay mark 40 includes an overlay pattern of an overlay mark of a mandrel structure and an overlay mark of a gate slot, and the subsequent overlay measurement step will be performed by a DBO measurement step. The fifth overlay mark 50 includes the overlap of a gate pattern and a gate slot, and the AEICD (after etch inspection critical dimension) step is performed.

The IBO measurement step, the DBO measurement step and the AEICD step mentioned here can be understood as different overlay measurement steps, and more detailed features will be described in the following paragraphs. Therefore, as mentioned above, when there are multiple layers of materials and it is necessary to overlap with different overlay measurement steps, it will be necessary to form multiple overlay marks in the scribe line SL. However, with the size of semiconductor devices getting smaller and smaller, the space of scribe lines is gradually insufficient, and each overlay mark in FIG. 1 occupies a certain area. In addition, in order to distinguish the material layer corresponding to each overlay mark conveniently, the material code is usually marked next to the overlay mark, for example, the numbers 30 and 4D below each overlay mark in FIG. 1. It can be understood that these codes may change with different manufacturers. In a word, with the current technology, multiple overlay marks will occupy more space, which is not conducive to miniaturization of components.

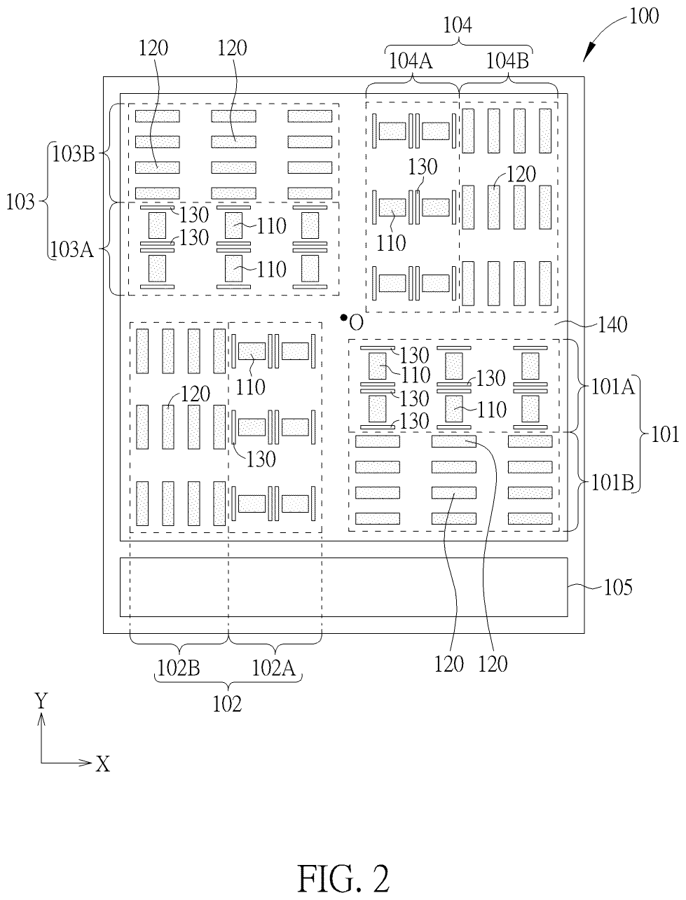

In order to solve the above problems, the present invention provides an improved overlay mark and a method for semiconductor overlay measurement using the overlay mark. FIG. 2 is a top view of the overlay mark of the present invention. As shown in FIG. 2, the overlay mark 100 provided in this embodiment is formed by arranging four sub-overlay marks, namely sub-overlay mark 101, sub-overlay mark 102, sub-overlay mark 103 and sub-overlay mark 104. Wherein each sub-overlay mark comprises an inner region and an outer region. From FIG. 2, there are different patterns in the inner region and the outer region, and the pattern in the inner region and the pattern in the outer region will be subjected to different overlay measurement steps in the following steps, such as IBO measurement step for the pattern in the inner region and the pattern in the outer region, or DBO measurement step for the pattern in the inner region and the patterns in other layers. Therefore, in the concept of the invention, different regions of the same overlay mark can be used for different overlay measurement steps respectively, that is to say, only one or a small number of overlay marks are needed to achieve the overlay measurement steps that can be completed by multiple overlay marks originally needed, so that the space occupied by overlay marks can be reduced, and the miniaturization of components can be facilitated.

In more detail, as shown in FIG. 2, taking the sub-overlay mark 101 in the overlay tag 100 as an example, the sub-overlay mark 101 includes an inner region 101A and an outer region 101B, wherein the inner region 101A includes a plurality of first mandrel structures 110 arranged in an array, and the outer region 101B includes a plurality of second mandrel structures 120 arranged in an array. The length, width or region of each first mandrel structure 110 and each second mandrel structure 120 are different. For example, each first mandrel structure 110 is rectangular and its long axis extends along the Y axis direction, while each second mandrel structure 120 is rectangular and its long axis extends along the X axis direction. In this embodiment, the length and the width of the first mandrel structure 110 and the width and the width of the second mandrel structure 120 are different from each other. In addition, the inner region 101A also includes a plurality of strip-shaped mask layers 130, wherein each strip-shaped mask layer 130 is preferably rectangular, and both sides of each first mandrel structure 110 respectively include a strip-shaped mask pattern 130. As shown in FIG. 2, the Y-axis sides of the first mandrel structure 110 respectively include strip-shaped mask layers 130, and the strip-shaped mask layers 130 are rectangular, and their long axes extend along the X-axis direction.

In addition, from the top view, the insulating layer 140 is located around each of the first mandrel structures 110 and each of the second mandrel structures 120, and the insulating layer 140 exposes each of the first mandrel structures 110 and each of the second mandrel structures 120, and the strip-shaped mask layer 130 is located above the insulating layer 140 (this part will be described more clearly when the cross-sectional structure is mentioned later). Similarly, except for the sub-overlay mark 101, which includes inner region 101A and outer region 101B, other sub-overlay marks also include inner region and other region. For example, the sub-overlay mark 102 includes inner region 102A and outer region 102B, the sub-overlay mark 103 includes inner region 103A and outer region 103B and the sub-overlay mark 104 includes inner region 104A and outer region 104B, as shown in FIG. 2. Among them, four sub-overlay marks are arranged in a windmill shape. As shown in FIG. 2, the windmill shape here divides the whole overlay mark 100 into four regions, namely, the upper right, the lower right, the upper left and the lower left, wherein the sub-overlay mark 101 and the sub-overlay mark 103 are located at both ends of one diagonal line, such as the lower right and the upper left respectively, and the inner region and the outer region of the sub-overlay mark 101 and the sub-overlay mark 103 are arranged along the Y direction. Similarly, the sub-overlay marker 102 and the sub-overlay marker 104 are located at two ends of another diagonal line, such as the lower left region and the upper right region, respectively, and the inner region and the outer region of the sub-overlay marker 102 and the sub-overlay marker 104 are arranged along the X direction, and the sub-overlay marker 102 and the sub-overlay marker 104 are in a 180-degree inverted pattern. And the four inner regions 101A, 102A, 103A and 104A are all located in the region near the center (inner region) of the overlay mark 100, that is, near the center point O, while the four outer regions 101B, 102B, 103B and 104B are all located in the region near the edge (outer region) of the overlay mark 100, that is, far from the center point O. Other windmill-like features are shown in FIG. 2.

In addition, the overlay mark 100 in FIG. 2 may also include a mark region 105, in which the mark region 105 can be used to annotate information, such as the number of the corresponding material layer, so as to facilitate the manufacturer to quickly identify the material layer to which the overlay mark belongs during the overlay measurement step. However, it can be understood that the mark region 105 is not a necessary element in the present invention, and in some embodiments, the mark region 105 can be omitted, which is also within the scope of the present invention.

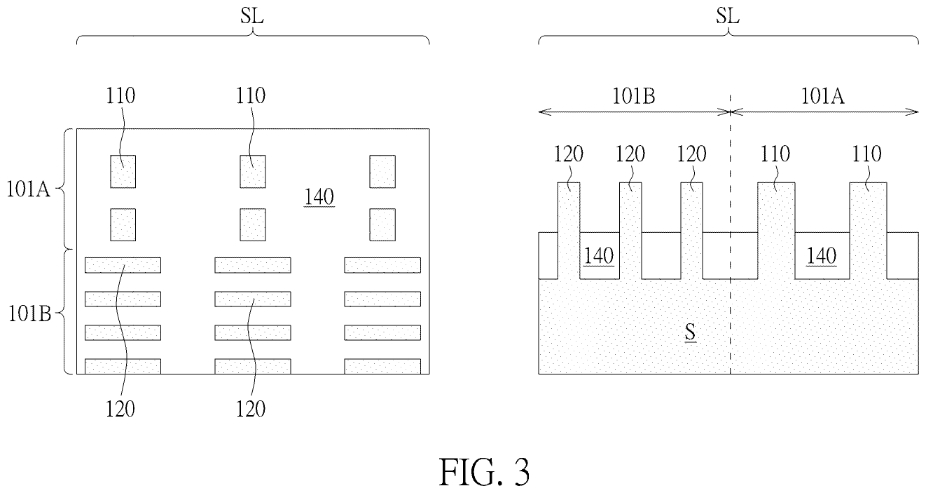

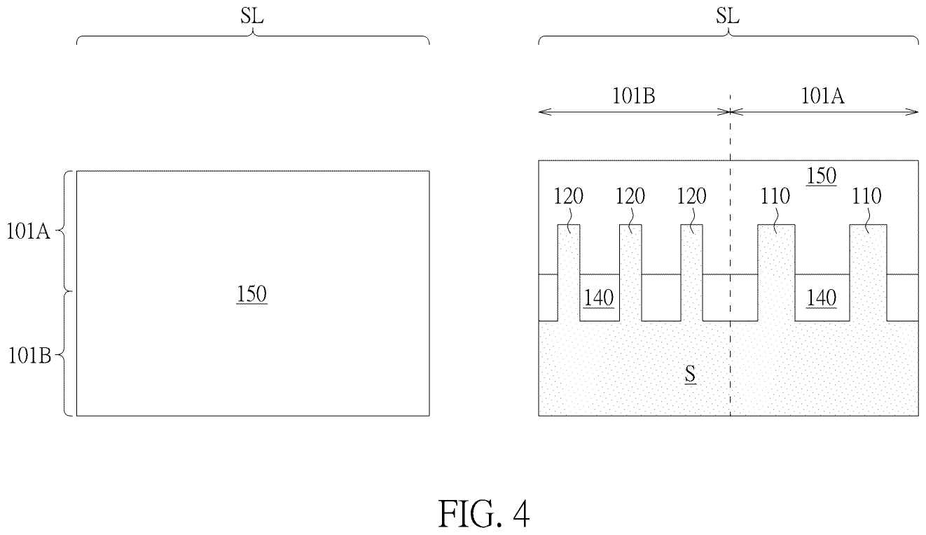

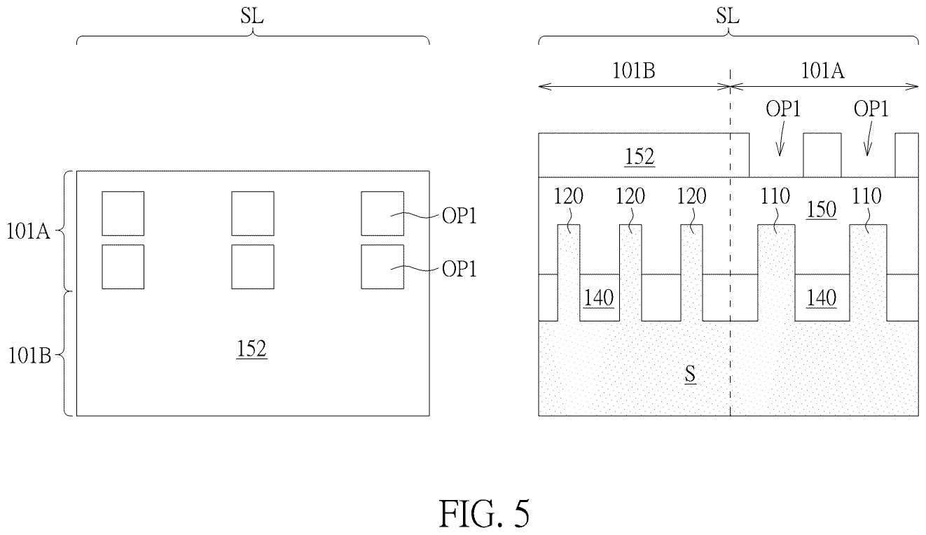

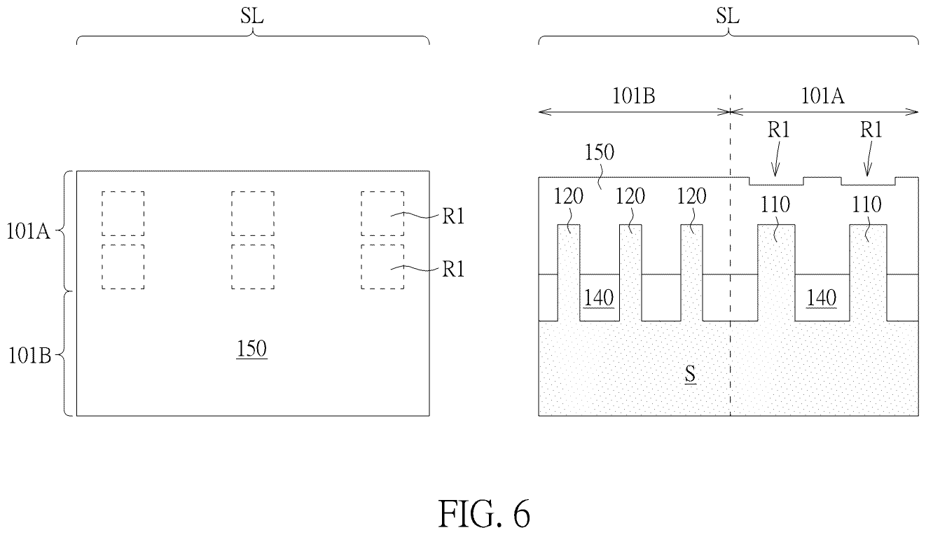

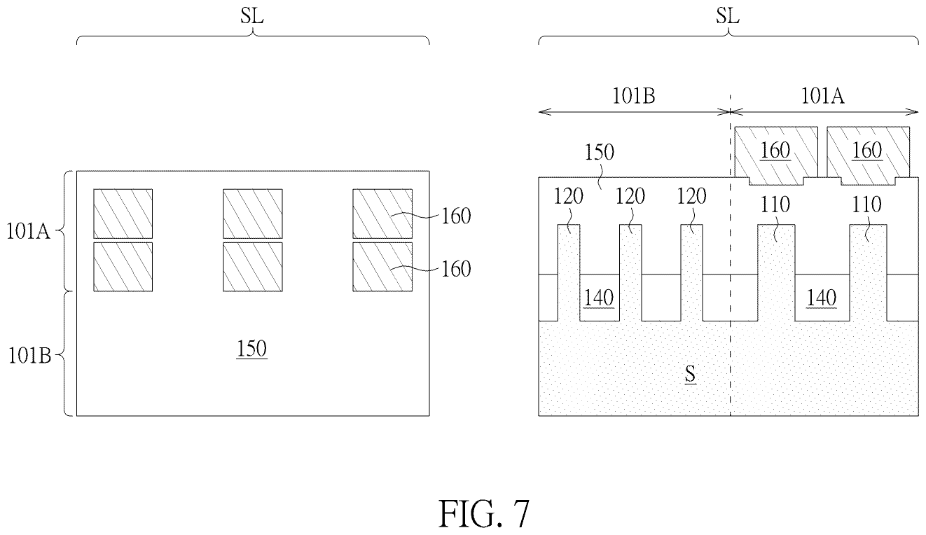

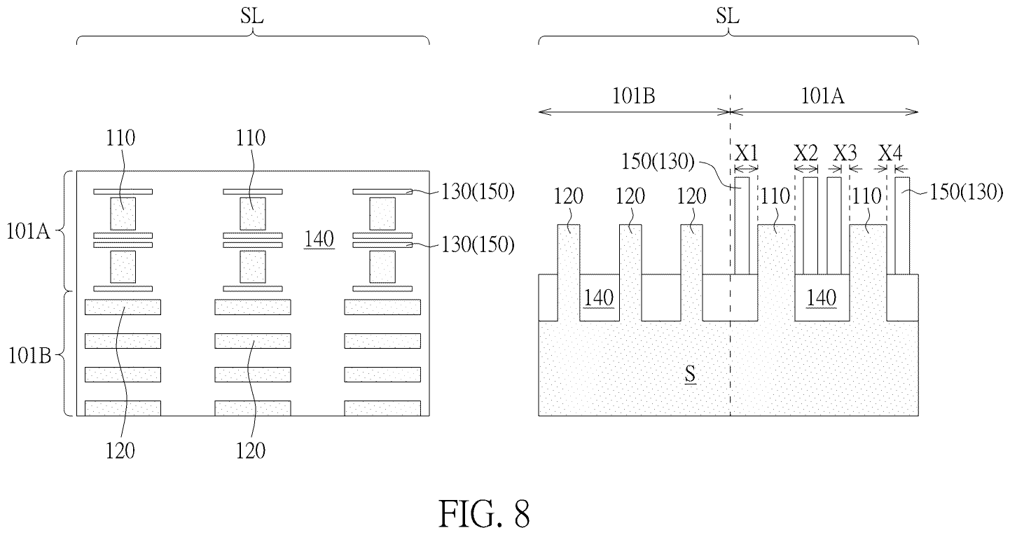

FIG. 2 is a schematic diagram showing the top view of the overlay mark in the scribe line after the mandrel structure process, the gate process and the gate cutting process are completed in the core region of the semiconductor structure. FIGS. 3, 4, 5, 6, 7, and 8 described below will describe a part of the top view and a part of the cross-sectional view of the overlay mark shown in FIG. 2. In which only a part of overlay marks, such as a part of sub-overlay mark 101 in FIG. 2 and the corresponding cross-sectional view, are drawn for simplicity of the drawing.

The left side of FIG. 3 shows a partial schematic top view of the overlay mark, and the right side of FIG. 3 shows the corresponding sectional structure. The following FIGS. 4 to 8 also show a partial schematic top view of the overlay mark on the left side and the corresponding sectional structure on the right side. As shown in FIG. 3, a plurality of first mandrel structures 110 and a plurality of second mandrel structures 120 are formed in the scribe line SL on the substrate S, wherein the first mandrel structures 110 are located in the inner region 101A and the second mandrel structures 120 are located in the outer region 101B. Here, the first mandrel structure 110 and the second mandrel structure 120 are formed together with the mandrel structure (mandrel) in the core region of the semiconductor device. As mentioned above, the mandrel structure in the core region will be made into a fin structure after the sidewall image transfer step. Here, for the sake of simplicity, the mandrel structure in the core region is not drawn.

In this embodiment, the length and width of the first mandrel structure 110 and the second mandrel structure 120 in the inner region 101A and the outer region 101B are designed to be different, so as to facilitate the identification of the first mandrel structure 110 and the second mandrel structure 120. In addition, after the first mandrel structure 110 and the second mandrel structure 120 are formed, an insulating layer 140 is formed to cover the substrate S, wherein the insulating layer 140 can be formed corresponding to shallow trench isolation (STI) in the core region of the semiconductor device, that is, together with the shallow trench isolation. As shown in FIG. 3, the insulating layer 140 is located around the first mandrel structure 110 and the second mandrel structure 120, and the insulating layer 140 exposes the first mandrel structure 110 and the second mandrel structure 120. In this embodiment, the material of the insulating layer 140 is, for example, silicon oxide, silicon nitride, silicon oxynitride, etc., but not limited thereto.

In this step, after the first mandrel structure 110 and the second mandrel structure 120 are formed, the positions of the first mandrel structure 110 and the second mandrel structure 120 can be recorded in a system (such as a computer) to facilitate the subsequent overlay measurement step. The details will be explained in the following paragraphs.

Next, as shown in FIG. 4, a mask layer 150 is formed to cover the insulating layer 140, the first mandrel structure 110 and the second mandrel structure 120. The material of the mask layer 150 is, for example, silicon oxide, silicon nitride, silicon oxynitride, and the material of the mask layer 150 is preferably different from that of the insulating layer 140.

As shown in FIG. 5, a first patterned photoresist layer 152 is formed above the mask layer 150, wherein the first patterned photoresist layer 152 includes a plurality of openings OP1, wherein the openings OP1 are located in the inner region 101A but not in the outer region 101B, and preferably the openings OP1 are located directly above the first mandrel structure 110. The opening OP1 described here may be formed at the same time as the gate cutting pattern (or the gate slot pattern) in the gate cutting step of the core region in the semiconductor manufacturing process. That is to say, in this step, a gate cutting pattern is defined in the core region of the semiconductor device. When the subsequent gate structure pattern is formed, the overlapping part of the gate structure pattern and the gate cutting pattern will be removed, and the last remaining gate pattern is the gate pattern that needs to be retained in the core region.

It is worth noting that in the above steps, the position of the gate cutting pattern is defined first, then the position of the gate pattern is defined, and finally the overlap between the two will be removed to keep the required gate pattern. However, in other embodiments of the present invention, the gate pattern can be formed first, and then the gate cutting pattern can be formed. Similarly, the overlapping part of the gate pattern and the gate cutting pattern will be removed, leaving the desired gate pattern. This variation is also within the scope of the present invention. Therefore, although the opening OP1 is formed at the same time as the gate cutting pattern in the core region in this embodiment, in other embodiments of the present invention, if the gate pattern is formed first, the opening OP1 here can also be formed at the same time as the gate pattern.

In this embodiment, when the opening OP1 is formed, the position of the gate cutting pattern in the core region is defined. Therefore, the position of the opening OP1 can be used for overlay measurement with other material layers to determine whether the gate cutting pattern is formed at the expected position without offset. As mentioned above (FIG. 1), in the current technology, if two overlay measurement steps are used, such as IBO step and DBO step, it is necessary to form two overlay marks in the scribe line, but in this embodiment, the inner region and outer region of one overlay mark can be used for the two overlay measurement steps respectively. Referring to FIG. 5 in more detail, the opening OP1 in the inner region 101A is located directly above the first mandrel structure 110, so the opening OP1 and the first mandrel structure 110 overlap from the top view, and a first diffraction based overlay measurement step DBO1, the so-called DBO measurement step, can be performed on the opening OP1 and the first mandrel structure 110. On the other hand, a first image based overlay measurement step IBO1, the so-called IBO step, can be performed between the position of the opening OP1 observed in the above view and the position of the second mandrel structure 120 located in the outer region 101B. Therefore, the pattern of the first patterned photoresist layer 152, that is, the position of the opening OP1 located in the inner region 101A, can be used to perform the first diffraction based overlay measurement step DBO1 with the first mandrel structure 110 located in the inner region 101A in the lower layer, and at the same time, it can be used to perform the first image based overlay measurement step IBO1 with the second mandrel structure 120 located in the outer region 101A in the lower layer.

Here are some details of the above-mentioned IBO measurement steps and DBO measurement steps. IBO step is an image based overlay technology, which is used to ensure that lithography patterns in semiconductor manufacturing process are accurately superimposed on previously formed patterns. IBO step uses high-resolution optical microscope or electron microscope to photograph the overlay mark pattern on the wafer, and uses image processing technology to calculate and correct the relative position error between layers. This method can provide very high overlay accuracy because it directly analyzes the actual features in the image rather than relying on the optical diffraction pattern. Its advantages include high accuracy and easy observation, but its equipment cost is high and the calculation amount is large. As for DBO step, it is based on diffraction overlay technology, which is used to overlay lithography patterns and formed patterns in semiconductor manufacturing. DBO step uses diffraction principle to measure the relative position of overlay marks. When the light beam irradiates the overlay marks on the wafer, the generated diffraction pattern can be captured by the detector. By analyzing these diffraction patterns, the relative position errors between overlay marks can be calculated and corrected. The advantages of DBO step include fast analysis speed, suitability for large-scale production, high accuracy, etc., while its disadvantages are that the technology is complex and easily limited by material structure, such as overlay marks. In a word, these two overlay measurement steps are all overlay measurement steps used in the present invention, but in fact, the present invention is not limited to these two overlay measurement steps, and other overlay measurement steps may also be included in the scope of the present invention.

Therefore, from the concept shown in FIG. 5 above, the inner region 101A and the outer region 101B of the same material layer (the first patterned photoresist layer 152) can be used for the IBO measurement step and the DBO measurement step respectively with the pattern of the lower layer, so that fewer overlay marks can be formed, and the space occupied by the scribe line can be saved.

In the above embodiment, the IBO measurement step and the DBO measurement step are respectively carried out, and after the overlay measurement step is completed, two sets of correction data will be obtained respectively, at this time, the manufacturer can select one set of data as the actual correction data according to the results. However, in other embodiments of the present invention, in order to save the process steps, only one of the overlay measurement steps, such as one of the IBO measurement step and the DBO measurement step, may be performed, and the obtained result is directly regarded as the correction data of this layer. This variation is also within the scope of the present invention.

Next, referring to FIG. 6, an etching step is performed using the first patterned photoresist layer 152 as a mask. After the etching, a recess R1 is formed in the mask layer 150, and then the first patterned photoresist layer 152 is removed. Here, the etching step can be performed simultaneously with the gate cutting step of the semiconductor core region, but it is not limited to this.

Next, as shown in FIG. 7, a second patterned photoresist layer 160 is formed on the mask layer 150, wherein the second patterned photoresist layer 160 can be formed simultaneously with the gate pattern in the core region. In this embodiment, the second patterned photoresist layer 160 can be used to overlap the position of the gate pattern, and the second patterned photoresist layer 160 is formed in the inner region 101A. Similarly to the above, the second patterned photoresist layer 160 located in the inner region 101A can perform the second diffraction based overlay measurement step DBO2 with the first mandrel structure 110 located in the inner region 101A below, and the second patterned photoresist layer 160 located in the inner region 101A can perform the second image based overlay measurement step IBO2 with the second mandrel structure 120 located in the outer region 101A below. The steps are similar to those shown in FIG. 5 above, so it will not be described here again. Therefore, similar to the above steps, when the second patterned photoresist layer 160 is formed, it can be used in different overlay measurement steps, and the second patterned photoresist layer 160 can be overlapped with the core structures in different regions respectively, so that it is unnecessary to make additional overlay marks and save the space of scribe lines.

Finally, as shown in FIG. 8, one or more photolithography etching steps are performed, where the overlapping part of the pattern of the first patterned photoresist layer 152 (that is, the position of the opening OP1) and the second patterned photoresist layer 160 is removed, and the remaining pattern is transferred to the lower mask layer 150, and finally the remaining mask layer 150 is shown in FIG. 8. It is worth noting that the mask layer 150 here is the same as the strip-shaped mask layer 130 described in FIG. 2. After the mask layer 150 shown in FIG. 8 is completed, the cut gate pattern is also formed in the core region of the semiconductor device.

In addition, after the etching step shown in FIG. 8 is completed, an after etch inspection critical dimension (AEICD) step can be performed. The AEICD step is often used to measure and inspect the dimensions of key structures on the wafer after the etching step is completed in the semiconductor manufacturing process, so as to ensure that the dimensions are within the expected range, that is, within the critical dimension (CD), so as to ensure the function and performance of the device. The AEICD step of this embodiment can also be used to measure whether there is a position shift between the gate pattern and the mandrel structure below the gate cutting pattern. In more detail, since the outer boundary of the etched strip-shaped mask layer 130 corresponds to the outer boundary of the second patterned photoresist layer 160, that is, the boundary corresponding to the gate pattern, the horizontal distance from the outer side of the remaining mask layer 150 (that is, the strip-shaped mask layer 130) to the side of the first mandrel structure 110 can be measured, such as the distance X1 and the distance X2 in FIG. 8, and then the distance X1 is subtracted from the distance X2 and divided by 2, so that the position offset between the lower first mandrel structure 110 corresponding to the gate pattern can be obtained.

It is worth noting that since the inner boundary of the etched strip-shaped mask layer 130 corresponds to the opening OP1 of the first patterned photoresist layer 152, that is, the boundary of the gate cutting pattern, the horizontal distance from the inner side of the remaining mask layer 150 (i.e., the strip-shaped mask layer 130) to the side of the first mandrel structure 110 can be measured, such as the distance X3 and the distance X4 in FIG. 8, and then the distance X3 is subtracted from the distance X4 and divided by 2, so that the position offset between the lower first mandrel structures 110 corresponding to the gate cutting pattern can be obtained.

That is to say, if the above-mentioned obtained gate pattern corresponds to the value of the position deviation between the lower first mandrel structures 110, or the value of the position deviation between the gate cutting pattern and the lower first mandrel structures 110 is almost close to zero, it means that the position of the gate pattern or the gate cutting pattern corresponding to the lower first mandrel structures is not shifted in the manufacturing process. On the contrary, if the above value exceeds an allowable range, it will shift in the detection step after etching, which also means that a position error may occur between the gate pattern, the gate cutting pattern and the underlying fin structure in the semiconductor core region. At this time, it is necessary to carry out a detection and process adjustment step to find errors and correct them in time.

In the current technology, in order to carry out the AEICD step, it is also necessary to form corresponding overlay marks on the scribe line, that is, the fifth overlay mark 50 in FIG. 1. However, the overlay mark 100 of the embodiment of the present invention has been subjected to a plurality of overlay measurement steps during its formation, including the first image based overlay measurement step IBO1, the first diffraction based overlay measurement step DBO1, the second image based overlay measurement step IBO2 and the second diffraction based overlay measurement step DBO2. In addition, after the etching is completed, an overlay measurement step of AEICD step is carried out. That is to say, the same overlay mark 100 of the present invention can be measured five times from the beginning of formation to the completion of etching. In the actual process, only the overlay mark 100 needs to be formed, which can replace the effect of five overlay marks in FIG. 1, and the number of overlay marks can be greatly reduced.

In addition, in the above embodiment, the gate cutting pattern is formed first, and then the gate pattern is formed, so the first patterned photoresist layer 152 corresponds to the gate cutting pattern, and the second patterned photoresist layer 160 formed later corresponds to the gate pattern, and the overlapping part of the two patterns will be removed, and the final pattern is the required gate pattern. However, in other embodiments of the present invention, the gate pattern may be formed first and then the gate cutting pattern may be formed, that is, the first patterned photoresist layer 152 may correspond to the gate pattern, the etching step shown in FIG. 6 may be performed simultaneously with the etching step of etching the gate pattern in the core region, and then the second patterned photoresist layer 160 may correspond to the gate cutting pattern, so the etching step shown in FIG. 8 corresponds to the etching step in the gate cutting step (i.e., removing part of the gate pattern) This variation is also within the scope of the present invention.

Based on the above description and drawings, the present invention provides an overlay mark, including four sub-overlay marks 101, 102, 103 and 104, which together form an overlay mark 100, wherein each sub-overlay mark includes a substrate S defining an inner region 101A and an outer region 101B, a plurality of first mandrel structures 110 located in the inner region 101A, and a plurality of second mandrel structures 120. Wherein the first mandrel structures 110 are arranged in parallel with each other, and the second mandrel structures 120 are also arranged in parallel with each other, and a plurality of strip-shaped mask layers 130 are located in the inner region 101A, wherein both sides of any first mandrel structure 110 include one strip-shaped mask layer 130.

In some embodiments of the present invention, the length of the first mandrel structure 110 and the width of the second mandrel structure 120 are different from each other (as shown in FIG. 3).

In some embodiments of the present invention, an insulating layer 140 is further included, which is located on the substrate S and exposes each of the first mandrel structures 110 and each of the second mandrel structures 120.

In some embodiments of the present invention, the insulating layer 140 is located on both sides of the first mandrel structure 110 and each second mandrel structure 120, and the strip-shaped mask layer 130 is located on the insulating layer 140.

In some embodiments of the present invention, the first mandrel structure 110 and each second mandrel structure 120 are directly connected to the substrate S.

In some embodiments of the present invention, two of the four sub-overlay marks (e.g., sub-overlay mark 102 and sub-overlay mark 104) are arranged along an X-axis direction, the other two sub-overlay marks (e.g., sub-overlay mark 101 and sub-overlay mark 103) are arranged along a Y-axis direction, and the four sub-overlay marks are arranged in a windmill shape.

The invention also provides an overlay measurement method of semiconductor structures, which comprises four sub-overlay marks (the sub-overlay marks 101, 102, 103 and 104) on a scribe line SL of a substrate S, wherein each sub-overlay mark contains an inner region 101A and an outer region 101B, and a plurality of first mandrel structures 110 are located on the substrate S of the inner region 101A, and a plurality of second mandrel structures 120 are located in the outer region 101B. A mask layer 150 is formed to cover the first mandrel structure 110 and the second mandrel structure 120, a first patterned photoresist layer 152 is formed on the mask layer 150, and the first patterned photoresist layer 152, the first mandrel structure 110 and the second mandrel structure 120 are subjected to a first overlay measurement step (including a first image based overlay measurement step IBO1 and a first diffraction based overlay measurement step DBO1). A second patterned photoresist layer 160 is formed on the mask layer 150, and the second patterned photoresist layer 160, the first mandrel structure 110 and the second mandrel structure 120 are subjected to a second overlay measurement step (including a second image based overlay measurement step IBO2 and a second diffraction based overlay measurement step DBO2).

In some embodiments of the present invention, the first overlay measurement step includes a first image based overlay measurement step IBO1 and a first diffraction based overlay measurement step DBO1.

In some embodiments of the present invention, the first image based overlay measurement step is to overlay the pattern (the opening OP1) of the first patterned photoresist layer 152 in the inner region 101A with the pattern of the second mandrel structure 120 in the outer region 101B.

In some embodiments of the present invention, the first diffraction based overlay measurement step is a diffraction overlay of the pattern (the opening OP1) of the first patterned photoresist layer 152 in the inner region 101A and the pattern of the first mandrel structure 110 in the inner region 101A.

In some embodiments of the present invention, the second overlay measurement step includes a second image based overlay measurement step IBO2 and a second diffraction based overlay measurement step DBO2.

In some embodiments of the present invention, the second image based overlay measurement step is to overlay the pattern of the second patterned photoresist layer 160 in the inner region 101A with the pattern of the second mandrel structure 120 in the outer region 101n.

In some embodiments of the present invention, the second diffraction based overlay measurement step is a diffraction overlay between the pattern of the second patterned photoresist layer 160 in the inner region 101A and the pattern of the first mandrel structure 110 in the inner region 101A.

In some embodiments of the present invention, an insulating layer 140 is formed on the substrate S, wherein the insulating layer 140 is located next to each first mandrel structure 110 and each second mandrel structure 120.

In some embodiments of the present invention, after the formation of the first patterned photoresist layer 152, a first etching step (as shown in FIG. 6) is further performed to remove a part of the mask layer 150, and then a second patterned photoresist layer 160 is formed on the remaining mask layer 150 (as shown in FIG. 7).

In some embodiments of the present invention, after the formation of the second patterned photoresist layer 160, a second etching step (step in FIG. 8) is further performed to remove part of the mask layer 150, and the remaining mask layers 150 are defined as a plurality of strip-shaped mask layers 130, wherein the strip-shaped mask layers 130 are located on the insulating layer 140.

In some embodiments of the present invention, after the second etching step, a after etching inspection critical dimension (AEICD) step (step shown in FIG. 8) is further performed to measure the distance between the strip-shaped mask layer 130 and the first mandrel structure 110.

In some embodiments of the present invention, the length of the first mandrel structure 110 and the length of the second mandrel structure 120 are different from each other, and the width of the first mandrel structure 110 and the width of the second mandrel structure 120 are different from each other too.

In some embodiments of the present invention, the first mandrel structure 110 and each second mandrel structure 120 are directly connected to the substrate.

In some embodiments of the present invention, two of the four sub-overlay marks 101, 102, 103, and 104 (e.g., the sub-overlay mark 102 and the sub-overlay mark 104) are arranged along an X-axis direction, and the other two sub-overlay marks (e.g., the sub-overlay mark 101 and the sub-overlay mark 103) are arranged along a Y-axis direction, and the four sub-overlay marks are arranged in a windmill shape.

To sum up, in the current technology, in order to improve the accuracy of overlay measurement steps, it may be carried out in several different overlay ways, including IBO (Image Based Overlay) measurement and DBO (Diffraction Based Overlay) measurement, etc. However, in the current technology, each overlay measurement step needs to form a separate overlay mark, when the size of components is getting smaller and smaller, too many overlay marks may not be accommodated in the limited space of the scribe line. The concept of the invention lies in that the same overlay mark is divided into different regions, such as an inner region and an outer region, and then the inner region and the outer region are respectively applied to different overlay measurement steps, such as an image based overlay (IBO) measurement step and a diffraction based overlay (DBO) measurement step. In other words, different regions of the same overlay mark can be used for different overlay measurement steps, so the original multiple overlay marks can be reduced to only a few overlay marks to complete the same overlay measurement step. In this way, the space of the scribe line can be greatly saved, and then the space of components can be saved. The invention conforms to the development trend of miniaturization of components and is also conducive to technical progress.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An overlay mark comprising:
four sub-overlay marks, which together form the overlay mark, wherein each sub-overlay mark comprises:
a substrate defining an inner region and an outer region;
a plurality of first mandrel structures located in the inner region and a plurality of second mandrel structures located in the outer region, wherein the first mandrel structures are arranged in parallel with each other, and the second mandrel structures are also arranged in parallel with each other;
a plurality of strip-shaped mask layers located in the inner region, wherein both sides of any first mandrel structure include one strip-shaped mask layer respectively.

2. The overlay mark according to claim 1, wherein the first mandrel structure and the second mandrel structure are different in length and width.

3. The overlay mark according to claim 1, further comprising an insulating layer located on the substrate and exposing each of the first mandrel structures and each of the second mandrel structures.

4. The overlay mark according to claim 3, wherein the insulating layer is located on both sides of the first mandrel structure and each of the second mandrel structures, and the strip mask layer is located on the insulating layer.

5. The overlay mark according to claim 1, wherein the first mandrel structure and the second mandrel structures are directly connected to the substrate.

6. The overlay mark according to claim 1, wherein two of the four sub-overlay marks are arranged along an X-axis direction, and the other two sub-overlay marks are arranged along a Y-axis direction, and the four sub-overlay marks are arranged in a windmill shape.

7. An overlay measurement method of a semiconductor structure, comprising:
forming four sub-overlay marks on a scribe line of a substrate, wherein each sub-overlay mark comprises an inner region and an outer region, and a plurality of first mandrel structures located on the substrate of the inner region, and a plurality of second mandrel structures located on the substrate of the outer region;
forming a mask layer to cover the first mandrel structure and the second mandrel structure;
forming a first patterned photoresist layer on the mask layer;
performing a first overlay measurement step on the first patterned photoresist layer, the first mandrel structure and the second mandrel structure;
forming a second patterned photoresist layer on the mask layer; and
performing a second overlay measurement step on the second patterned photoresist layer, the first mandrel structure and the second mandrel structure.

8. The overlay measurement method of semiconductor structure according to claim 7, wherein the first overlay measurement step comprises a first image based overlay measurement step and a first diffraction based overlay measurement step.

9. The overlay measurement method of semiconductor structure according to claim 8, wherein the first image based overlay measurement step is an image overlay of the pattern of the first patterned photoresist layer in the inner region and the pattern of the second mandrel structure in the outer region.

10. The overlay measurement method of semiconductor structure according to claim 8, wherein the first diffraction based overlay measurement step is a diffraction overlay of the pattern of the first patterned photoresist layer in the inner region and the pattern of the first mandrel structure in the inner region.

11. The overlay measurement method of semiconductor structure according to claim 7, wherein the second overlay measurement step comprises a second image based overlay measurement step and a second diffraction based overlay measurement step.

12. The overlay measurement method of a semiconductor structure according to claim 11, wherein the second image based overlay measurement step is an image overlay of the pattern of the second patterned photoresist layer in the inner region and the pattern of the second mandrel structure in the outer region.

13. The overlay measurement method of semiconductor structure according to claim 11, wherein the second diffraction based overlay measurement step is a diffraction overlay of the pattern of the second patterned photoresist layer in the inner region and the pattern of the first mandrel structure in the inner region.

14. The overlay measurement method of semiconductor structures according to claim 7, further comprising forming an insulating layer on the substrate, wherein the insulating layer is located beside each of the first mandrel structures and each of the second mandrel structures.

15. The overlay measurement method of semiconductor structure according to claim 14, wherein after the formation of the first patterned photoresist layer, a first etching step is further performed to remove a part of the mask layer, and then the second patterned photoresist layer is formed on the remaining mask layer.

16. The overlay measurement method of a semiconductor structure according to claim 15, wherein after the formation of the second patterned photoresist layer, a second etching step is further performed to remove part of the mask layer, and the remaining mask layers are defined as a plurality of strip-shaped mask layers, wherein the strip-shaped mask layers are located on the insulating layer.

17. The overlay measurement method of semiconductor structure according to claim 16, wherein after the second etching step, it further comprises an after etch inspection critical dimension (AEICD) step to measure the distance between the strip-shaped mask layer and the first mandrel structure.

18. The overlay measurement method of semiconductor structures according to claim 7, wherein a length of the first mandrel structure and a length of the second mandrel structure are different, and a width of the first mandrel structure and a width of the second mandrel structure are also different.

19. The overlay measurement method of semiconductor structures according to claim 7, wherein the first mandrel structure and the second mandrel structures are directly connected to the substrate.

20. The overlay measurement method of semiconductor structure according to claim 7, wherein two of the four sub-overlay marks are arranged along an X-axis direction, and the other two sub-overlay marks are arranged along a Y-axis, and the four sub-overlay marks are arranged in a windmill shape.
